(19) United States
(12) Patent Application Publication
(10) Pub. No.: US 2019/0088725 A1
(43) Pub. Date: Mar. 21, 2019

(54) DISPLAY DEVICE AND METHOD OF MANUFACTURING DISPLAY DEVICE

(71) Applicant: JOLED INC., Tokyo (JP)

(72) Inventor: Hiroki YAMAMOTO, Tokyo (JP)

(73) Assignee: JOLED INC., Tokyo (JP)

(21) Appl. No.: 16/044,676

(22) Filed: Jul. 25, 2018

(30) Foreign Application Priority Data
Sep. 19, 2017 (JP) 2017-179101

(51) Int. Cl. H01L 27/32; H01L 51/56; H01L 51/52

(52) U.S. Cl. CPC H01L 27/3244; H01L 51/56; H01L 51/5206; H01L 2251/5315; H01L 27/322; H01L 2227/32; H01L 51/5221

(57) ABSTRACT

A display device including: an organic EL element that is provided in each of pixels and emits light according to flow of current; and a resistance element that is provided in each of the pixels and is connected in parallel to the organic EL element. Resistance of the light-emitting element and resistance of the resistance element increase over time after energization of the light-emitting element and the resistance element. The resistance of the resistance element is higher than the resistance of the organic EL element.

### CROSS REFERENCE TO RELATED APPLICATION

The present application is based on and claims priority of Japanese Patent Application No. 2017-179101 filed on Sep. 19, 2017. The entire disclosure of the above-identified application, including the specification, drawings and claims is incorporated herein by reference in its entirety.

### FIELD

The present disclosure relates to a display device and a method of manufacturing the display device, and particularly relates to an organic electroluminescence (EL) display device having organic EL elements, and a method of manufacturing the organic EL display device. The present disclosure relates to a display device and a method of manufacturing the display device, and particularly relates to an organic electroluminescence (EL) display device having organic EL elements, and a method of manufacturing the organic EL display device.

### BACKGROUND

In recent years, organic EL display devices utilizing organic EL elements have drawn attention as selfluminous display devices having excellent response with high contrast and wide view angle. In particular, the development of active matrix organic EL display devices that are advantageous for use in high definition and large screen devices has been active.

An active matrix organic EL display device has, for example, pixels arranged in matrix, each pixel including an organic EL element and a pixel circuit for supplying the organic EL element with a driving current (see reference, for example, to Patent Literature 1).

### CITATION LIST

### Patent Literature

[Patent Literature 1] Japanese Unexamined Patent Application Publication No. 2009-186982

### SUMMARY

### Technical Problem

Luminance of a light-emitting element such as an organic EL element decreases due to the deterioration of the light-emitting element. Accordingly, the problem observed in selfluminous display devices is screen burn-in caused by the deterioration of light-emitting elements.

The technology disclosed in the present disclosure has an object to provide a display device with which luminance decrease can be prevented even though light-emitting elements deteriorate, and a method of manufacturing the display device.

### Solution to Problem

In order to achieve the above-described object, a display device according to one aspect of the present disclosure includes: a light-emitting element that is provided in each of pixels and emits light according to flow of current; and a resistance element that is provided in each of the pixels and is connected in parallel to the light-emitting element. Resistance of the light-emitting element and resistance of the resistance element increase over time after energization of the light-emitting element and the resistance element, and the resistance of the resistance element changes at a higher rate than the resistance of the light-emitting element.

Moreover, a method of manufacturing a display device according to one aspect of the present disclosure includes: forming a bank that has an opening; forming a first charge functional layer by applying a first material inside the opening and drying the first material applied; forming a light-emitting layer on the first charge functional layer by applying a second material inside the opening and drying the second material applied; and forming a second charge functional layer on the light-emitting layer to cover the opening. The first charge functional layer and the second charge functional layer are close to or in contact with each other at a lateral wall of the bank.

### Advantageous Effects

It is possible to prevent luminance decrease even though light-emitting elements deteriorate.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is an exploded perspective view schematically illustrating an organic EL display device according to an embodiment.

FIG. 2 is a diagram illustrating an electric circuit including a pixel circuit and an EL portion that are included in each pixel in the organic EL display device according to the embodiment.

FIG. 3 is a cross-sectional perspective view schematically illustrating the configuration of a portion of the organic EL display device according to the embodiment.

FIG. 4 is an enlarged view illustrating region IV enclosed by a dashed line in FIG. 3.

FIG. 5 is a diagram illustrating a change in the amount of current when an organic EL element in a conventional organic EL display device deteriorates.

FIG. 6 is a diagram illustrating a change in the amount of current when an organic EL element and a resistance element in the organic EL display device according to the embodiment deteriorate.

FIG. 7 is a diagram illustrating a change in the luminance of an organic EL element with respect to a period of energization time.

FIG. 8A is a cross-sectional view illustrating a process of preparing a TFT substrate in a method of manufacturing the organic EL display device according to the embodiment.

FIG. 8B is a cross-sectional view illustrating a process of forming an anode of an organic EL element, in the method of manufacturing the organic EL display device according to the embodiment.

FIG. 8C is a cross-sectional view illustrating a process of applying a resist film intended for bank, in the method of manufacturing the organic EL display device according to the embodiment.

FIG. 8D is a cross-sectional view illustrating a process of exposing, to light, a resist film intended for bank, in the method of manufacturing the organic EL display device according to the embodiment.

FIG. 8E is a cross-sectional view illustrating a process of developing the resist film intended for bank, in the method of manufacturing the organic EL display device according to the embodiment.

FIG. 8F is a cross-sectional view illustrating a process of removing a mask at the time of exposing, to light, the resist film intended for bank, in the method of manufacturing the organic EL display device according to the embodiment.

FIG. 8G is a cross-sectional view illustrating a process of applying the first organic solvent intended for hole injection layer of the organic EL element, in the method of manufacturing the organic EL display device according to the embodiment.

FIG. 8H is a cross-sectional view illustrating a process of drying the first organic solvent intended for hole injection layer of the organic EL element, in the method of manufacturing the organic EL display device according to the embodiment.

FIG. 8I is a cross-sectional view illustrating a process of applying the second organic solvent intended for light-emitting layer of the organic EL element, in the method of manufacturing the organic EL display device according to the embodiment.

FIG. 8J is a cross-sectional view illustrating a process of drying the second organic solvent intended for light-emitting layer of the organic EL element, in the method of manufacturing the organic EL display device according to the embodiment.

FIG. 8K is a cross-sectional view illustrating a process of forming an electron transport layer of the organic EL element, in the method of manufacturing the organic EL display device according to the embodiment.

FIG. 8L is a cross-sectional view illustrating a process of forming a cathode of the organic EL element, in the method of manufacturing the organic EL display device according to the embodiment.

### DESCRIPTION OF EMBODIMENT

The following describes exemplary embodiments with reference to the drawings. Note that each of the embodiments described below is merely one specific example of the present disclosure. Accordingly, the numerical values, shapes, materials, elements, arrangement and connection of the elements, etc., indicated in the following embodiments are given merely by way of illustrations and are not intended to limit the scope of the present disclosure. Therefore, among the elements in the following embodiments, those not recited in any one of the independent claims defining the broadest concepts of the present disclosure are described as optional elements.

Note also that the figures are schematic illustrations and are not necessarily precise depictions. Therefore, the scale sizes in the figures, for example, are not necessarily the same. Moreover, in the figures, elements that are essentially the same share like reference signs and duplicate description is omitted or simplified.

### Embodiment

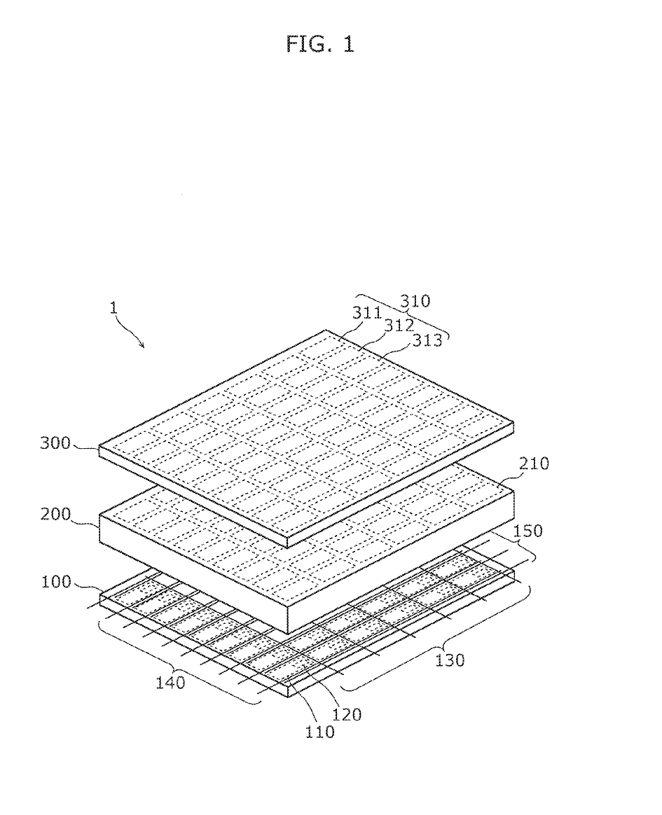

The following describes, as an example of a display device, organic EL display device 1 having organic EL elements 210. FIG. 1 is an exploded perspective view schematically illustrating organic EL display device 1 according to an embodiment.

As illustrated in FIG. 1, organic EL display device 1 includes TFT substrate 100, EL portion 200, and color-filter substrate 300. TFT substrate 100, EL portion 200, and color-filter substrate 300 are laminated from bottom to top in the listed order. In other words, EL portion 200 is disposed on TFT substrate 100 and color-filter substrate 300 is disposed on EL portion 200. More specifically, EL portion 200 is formed on a planarization layer of TFT substrate 100. Moreover, EL portion 200 and color-filter substrate 300 are attached by an attaching layer (not shown in the diagram).

TFT substrate 100 is a TFT array substrate that has thin film transistors (TFTs). TFT substrate 100 has, in each of pixels 110 arranged in matrix, pixel circuit 120 formed from circuit elements such as TFTs and condensers. TFT substrate 100 has, for example, a substrate such as a glass substrate or a transparent resin substrate, wiring layers each including electrodes of the TFTs and wirings, and an interlayer insulating layer formed between the wiring layers.

More specifically, TFT substrate 100 has, as plural wirings, gate lines (scanning lines) 130 aligned in the row direction of pixels 110, source lines (signal lines) 140 aligned in the column direction of pixels 110 to orthogonally intersect with gate lines 130, and power lines 150 disposed substantially in parallel to source lines 140. Each pixel 110 is sectioned, for example, by gate lines 130 and source lines 140 that orthogonally intersect with each other.

Gate line 130 is connected, on a per row basis, to a gate electrode of a switching transistor included in each pixel circuit 120. Source line 140 is connected, on a per column basis, to a source electrode of a switching transistor included in each pixel circuit 120. Source line 150 is connected, on a per column basis, to a source electrode of a switching transistor included in each pixel circuit 120.

EL portion 200 includes organic EL element 210 provided in each of pixels 110. Organic EL element 210 in each pixel 110 is an example of a light-emitting element and the drive of organic EL element 210 is controlled by pixel circuit 120 in each pixel 110. In other words, the light emission of each organic EL element 210 is controlled by pixel circuit 120. More specifically, since organic EL element 210 emits light according to the flow of current to organic EL element 210, it is possible to cause organic EL element 210 to emit light by supplying organic EL element 210 with current by means of pixel circuit 120.

Organic EL element 210 is formed on TFT substrate 100. To be more specific, a planarization layer is formed in the upper layer of TFT substrate 100 and organic EL element 210 is formed on the planarization layer. Organic EL element 210 has a structure in which an anode, a light-emitting layer, and a cathode are laminated, which will be described in detail later on.

Color-filter substrate 300 has color filters 310 formed on a transparent substrate which is a glass substrate or a transparent resin substrate. In this embodiment, color filters 310 include red filter 311, green filter 312, and blue filter 313. Red filter 311 transmits red light emitted from EL portion 200. Green filter 312 transmits green light emitted from EL portion 200. Blue filter 313 transmits blue light emitted from EL portion 200.

Organic EL display device 1 having such a configuration as described above is of top emission type and causes light emitted by organic EL element 210 to exit from a color-filter substrate 300 side (a side opposite to a TFT substrate 100 side). Note that organic EL display device 1 shall not be limited to a top emission type organic EL display device and may be a bottom emission type organic EL display device which causes light emitted by organic EL element 210 to exit from the TFT substrate 100 side. With a top emission type organic EL display device, it is possible to increase an aperture ratio thereof compared with a bottom emission type organic EL display device. Therefore, with a top emission type organic EL display device, efficiency in light emission is more enhanced than with a bottom emission type organic EL display device.

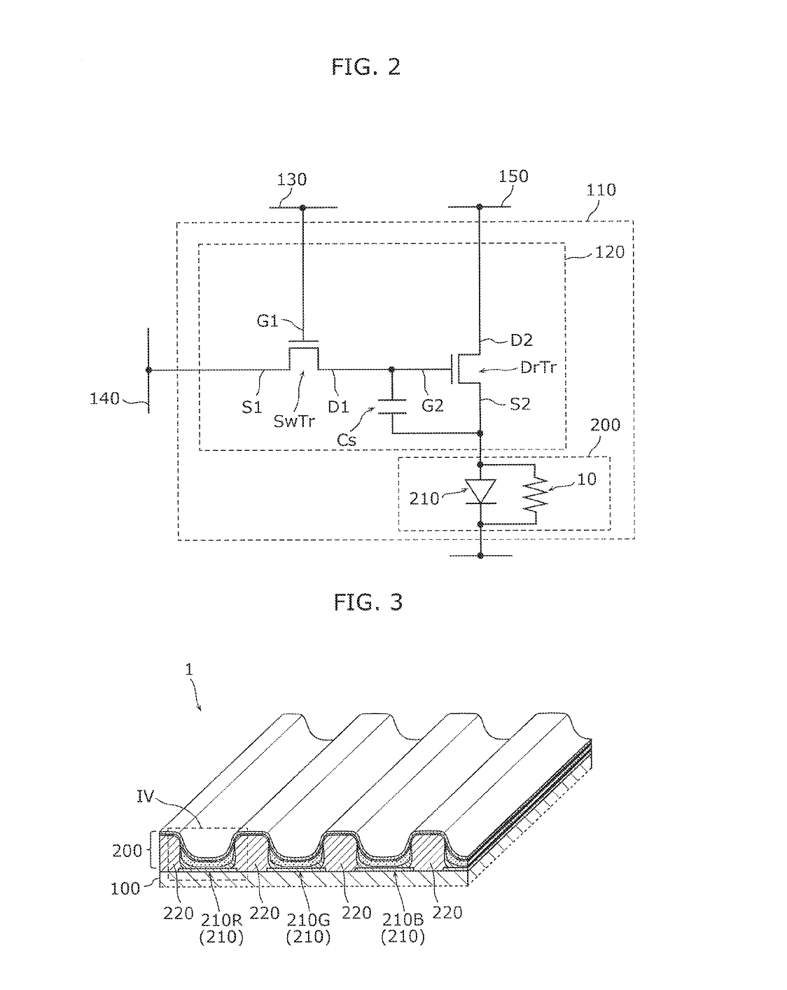

Next, the configurations of pixel circuit 120 of TFT substrate 100 and EL portion 200 that are included in each pixel 110 of organic EL display device 1 will be described with reference to FIG. 2. FIG. 2 is a diagram, illustrating an electric circuit including pixel circuit 120 and EL portion 200 that are included in each pixel 110 of organic EL display device 1 according to the embodiment.

Pixel circuit 120 in each pixel 110 is a constant current circuit for supplying organic EL element 210 with a drive current for causing organic EL element 210 to emit light, and has circuit elements such as TFTs. In this embodiment, each pixel circuit 120 has a 2Tr1C circuit configuration having, as circuit elements, two TFTs and one condenser.

More specifically, each pixel circuit 120 is formed from a TFT formed as driving transistor DrTr, a TFT formed as switching transistor SwTr, and condenser Cs formed as a storage capacitor that stores data voltage (signal voltage), as illustrated in FIG. 2.

Driving transistor DrTr is a TFT for driving organic EL element 210 and controls the current that flows to organic EL element 210. Moreover, switching transistor SwTr is a TFT for selecting pixel 110 caused to emit light (i.e., organic EL element 210 caused to emit light) among pixels 110. Switching transistor SwTr is connected to gate electrode G2 which is a control terminal of driving transistor DrTr, and controls conduction and non-conduction of driving transistor DrTr.

Switching transistor SwTr includes gate electrode G1 connected to gate line 130, source electrode S1 connected to source line 140, drain electrode D1 connected to one electrode of condenser Cs as well as gate electrode G2 of driving transistor DrTr, and a semiconductor layer (not shown in the diagram) that functions as a channel layer. When a predetermined voltage is applied to gate line 130 and source line 140 to which switching transistor SwTr is connected, the voltage applied to source line 140 is held as data voltage by condenser Cs.

Driving transistor DrTr includes: gate electrode G2 connected to drain electrode D1 of switching transistor SwTr and the other electrode of condenser Cs; drain electrode D2 connected to power line 150; source electrode S2 connected to an anode of organic EL element 210 and the other electrode of condenser Cs; and a semiconductor layer (not shown in the diagram) that functions as a channel layer. Driving transistor DrTr supplies the anode of organic EL element 210 with current in accordance with the data voltage held by condenser Cs from power line 150 through source electrode S2. With this, a drive current flows through organic EL element 210 from the anode to the cathode and a light-emitting layer in organic EL element 210 emits light. Then, by controlling the amount of current during energization of organic EL element 210 (amount of energization), it is possible to control the luminance of light emitted by organic EL element 210.

Active matrix scheme for controlling light emission for each pixel 110 is adopted for organic EL display device 1 configured as described above. In other words, by causing organic EL elements 210 arranged in matrix to selectively emit light, using switching transistor SwTr and driving transistor DrTr in each pixel 110, it is possible to cause organic EL display device 1 to display a desired image.

Moreover, EL portion 200 has, in each of pixels 110, resistance element 10 connected in parallel to organic EL element 210, as illustrated in FIG. 2. Each of organic EL element 210 and resistance element 10 has properties such that resistance increases over time after the energization of these elements. In this embodiment, the resistance of organic EL element 210 and the resistance of resistance element 10 gradually increase due to deterioration over time after energization during normal operation. Moreover, the resistance of resistance element 10 changes at a rate higher than the resistance of organic EL element 210 in this embodiment. That is to say, the rate of change at which resistance increases is higher in resistance element 10 than in organic EL element 210.

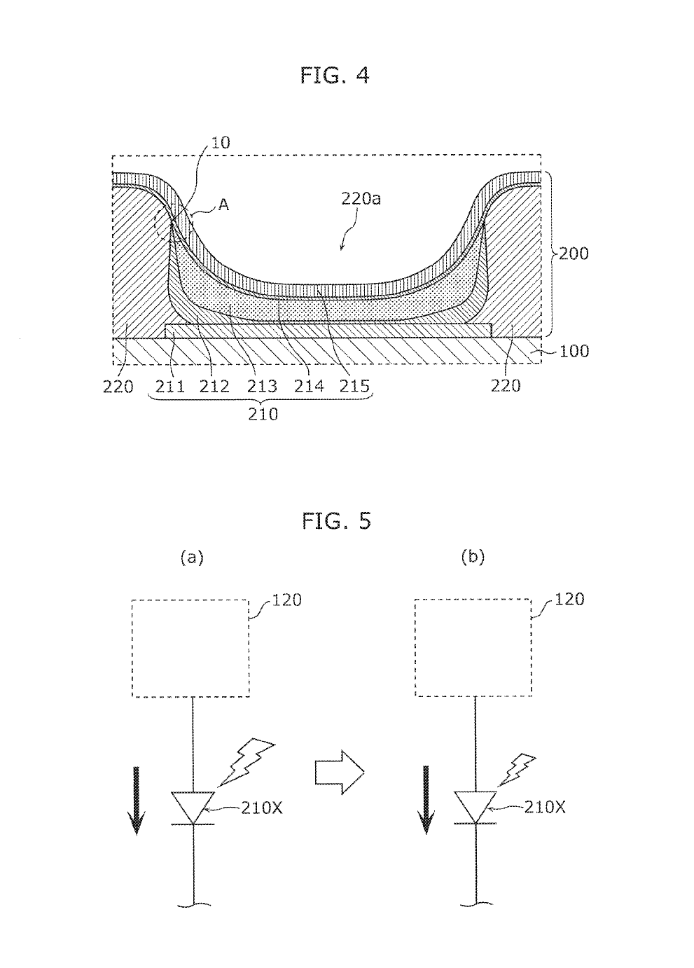

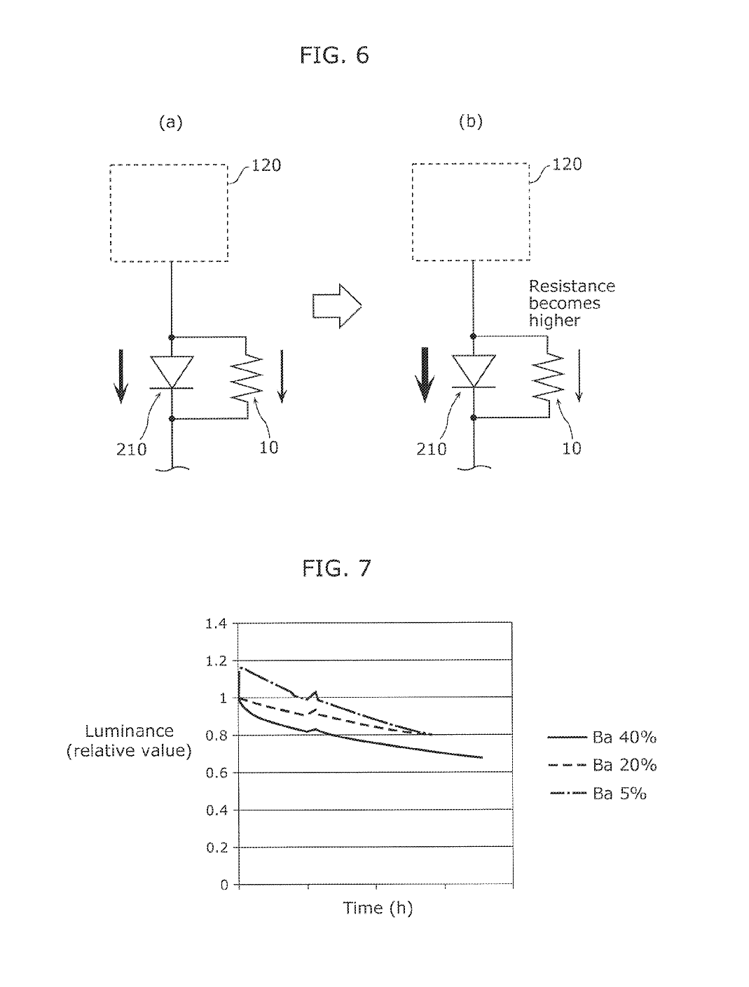

Next, detailed configurations of organic EL element 210 and resistance element 10 in organic EL display device 1 will be described with reference to FIG. 3 and FIG. 4. FIG. 3 is a cross-sectional perspective view schematically illustrating the configuration of a portion of organic EL display device 1 according to the embodiment. FIG. 4 is an enlarged view illustrating region IV that is enclosed by a dashed line and is illustrated in FIG. 3.

Pixels 110 in organic EL display device 1 include a red pixel, a green pixel, and a blue pixel. Organic EL elements 210 include organic EL element for red color 210R corresponding to a red pixel, organic EL element for green color 210G corresponding to a green pixel, and organic EL element for blue color 210B corresponding to a blue pixel, as illustrated in FIG. 3. Organic EL element for red color 201R emits red light, organic EL element for green color 210G emits green light, and organic EL element for blue color 210B emits blue light.

Organic EL elements 210 (organic EL element for red color 210R, organic EL element for green color 210G, and organic EL element for blue color 210B) are separated from each other by banks 220. In this embodiment, banks 220, each being a line bank, are formed, for example, from elongated protrusions each extending substantially in parallel to source lines 140. It should be noted that bank 220 shall not be limited to a line bank and may be a grid-like pixel bank.

Each of organic EL elements 210 (organic EL element for red color 210R, organic EL element for green color 210G, and organic EL element for blue color 2105) has: anode 211 which is the first electrode; hole injection layer 212 which is the first charge functional layer; light-emitting layer 213; electron transport layer 214 which is the second charge functional layer; and cathode 215 which is the second electrode.

As illustrated in FIG. 4, anode 211 is a lower electrode having a predetermined shape and is formed on TFT substrate 100. Anode 211 is formed inside opening 220a of bank 220 in each pixel 110. More specifically, anode 211 is formed in the bottom of opening 220a of bank 220.

In this embodiment, anode 211 is a reflecting electrode having light-reflecting properties and has a function to reflect light generated in light-emitting layer 213. Anode 211 includes, as a light-reflecting layer, a metallic layer composed of a metallic material such as aluminum.

In addition, anode 211 may have a structure in which a metallic layer composed of aluminum alloy and a transparent layer that is composed of oxidized tungsten and is formed on the metallic layer are laminated. In this case, the layer composed of oxidized tungsten may function not as anode 211, but as hole injection layer 212. The thickness of anode 211 is in the range of, for example, from 50 nm to 700 nm.

Hole injection layer (HIL) 212 is located between anode 211 and light-emitting layer 213, and has a function to inject a hole into light-emitting layer 213. Hole injection layer 212 is composed, for example, of an organic material including polythiophene series such as polyethylenedioxythiophene (PEDOT), phthalocyanine series, oligoamine series, dendrimeramine series, etc. Since it is desirable that hole injection layer 212 have lower resistance than light-emitting layer 213, it is recommended to select, for the material of hole injection layer 212, a material that has lower resistance than the material of light-emitting layer 213.

Hole injection layer 212 is formed inside opening 220a of bank 220 in each pixel 110. In this embodiment, hole injection layer 212 is disposed on anode 211 in such a manner to be surrounded by banks 220.

More specifically, hole injection layer 212 has a thin-filmed shape and rides on bank 220, extending from the bottom of opening 220a of bank 220 and along the lateral wall of bank 220. Moreover, the thickness of hole injection layer 212 is thin and is approximately the same at the center in the bottom of opening 220a of bank 220, but becomes gradually thicker toward the root of bank 220 and then becomes gradually thinner from the bottom toward the top along the lateral wall of bank 220. The thickness at the center of hole injection layer 212 is in the range of, for example, from 5 nm to 100 nm. Hole injection layer 212 having such a shape can be formed by applying, inside opening 220a, an organic material composing hole injection layer 212, and then drying the organic material applied.

Light-emitting layer 213 (EML) is located between anode 211 and cathode 215, and has a function to emit light when a light-emitting material is excited by energy generated through the recombination of holes and electrons injected upon the application of a predetermined voltage to anode 211 and cathode 215. In this embodiment, light-emitting layer 213 is located between hole injection layer 212 and electron transport layer 214.

In addition, it is possible to cause light-emitting layer 213 to emit light having a predetermined color (wavelength), by selecting a material for light-emitting layer 213. Light-emitting layer 213 is, for example, either one of a red-light emitting layer that emits red light, a green-light emitting layer that emits green light, or a blue-light emitting layer that emits blue light.

Light-emitting layer 213 is an organic light-emitting layer for which an organic light-emitting material is used. A low-molecular organic material such as aluminum-quinolinol complex (Alq3) or a high polymer organic material such as a polymer light-emitting material, e.g., polyparaphenylene vinylene (PPV) and polyfluorene, can be used as the organic light-emitting material composing light-emitting layer 213. Since it is desirable that light-emitting layer 213 have higher liquid repellency than that of hole injection layer 212 (i.e., it is desirable that a contact angle of light-emitting layer 213 be larger than that of hole injection layer 212), it is recommended to select, for the material of light-emitting layer 213, a material that has higher liquid repellency than the material of hole injection layer 212.

Light-emitting layer 213 is formed inside opening 220a of bank 220 in each pixel 110. In this embodiment, light-emitting layer 213 is disposed on hole injection layer 212 in such a manner to be surrounded by banks 220.

More specifically, light-emitting layer 213 has a thin-filmed shape and rides on bank 220, extending from the bottom of opening 220a of bank 220 and along the lateral wall of bank 220, and also along the surface of hole injection layer 212. The thickness of light-emitting layer 213 is approximately the same at the center of the bottom of opening 220a of bank 220, and becomes gradually thinner toward bank 220. The thickness, at the center, of light-emitting layer 213 is in the range of, for example, from 30 nm to 200 nm. Light-emitting layer 213 having such a shape can be formed by applying, inside opening 220a, an organic material composing light-emitting layer 213 of bank 200 and then drying the organic material applied.

Electron transport layer (EFL) 214 is located between light-emitting layer 213 and cathode 215, and has a function to transport electrons to light-emitting layer 213. An organic material such as metallic chelate, phenanthroline, oxadiazole, or triazole series or an inorganic material such as an alkali metal compound or an alkali earth metal compound are used as the material of electron transport layer 214.

Moreover, it is desirable that electron transport layer 214 include reducing metal. Barium, titanium, sodium, or aluminum can be used as the reducing metal for electron transport layer 214. In this embodiment, electron transport layer 214 is composed of an organic material including barium. The concentration of barium doped in electron transport layer 214 is in the range of from 1 wt. % to 50 wt % with respect to the weight of the material used for electron transport layer 214.

Electron transport layer 214 is formed on light-emitting layer 213 to cover opening 220a of bank 220. In this embodiment, electron transport layer 214 is formed continuously on light-emitting layer 213 over all of pixels 110 across banks 220. To be more specific, electron transport layer 214 is a thin-filmed monolayer and is formed over all of pixels 110 to cover openings 220a of all of banks 220 and along the surfaces of light-emitting layers 213 and banks 220. The thickness of electron transport layer 214 is approximately the same and is in the range of, for example, from 30 nm to 100 nm. Note that electron transport layer 214 shall not be limited to a monolayer and may be formed per plural pixels 110 inside opening 220a of bank 220, as is formed hole injection layer 212.

Cathode 215 is formed on electron transport layer 214 to face anode 211. In this embodiment, cathode 215 is formed continuously across banks 220, as is formed electron transport layer 214. Stated differently, cathode 215 is a common electrode commonly provided for pixels 110. To be more specific, cathode 215 is a thin-filmed monolayer and is formed over all of pixels 110 to cover openings 220a of all of banks 220 and along the surface of electron transport layer 214. The thickness of cathode 215 is approximately the same and is in the range of, for example, from 20 nm to 200 nm. Note that cathode 215 shall not be limited to a monolayer and may be formed per plural pixels 110 inside opening 220a of bank 220.

Moreover, organic EL display device 1 according to this embodiment is of top emission type, and therefore, cathode 215 is composed of a material having light transmissivity. Cathode 215 is, for example, a transparent conductive layer (transparent electrode) composed of indium tin oxide (ITO) or transparent metallic oxide such as indium zinc oxide (IZO). Note that the material itself of cathode 215 need not be transparent and cathode 215 may be a metal film composed, for example, of silver (Ag) or aluminum (Al) and may be rendered thinner to transmit light.

In organic EL element 210 having the configuration as described above, when voltage is applied between anode 211 and cathode 215, holes are injected from anode 211 to hole injection layer 212 and electrons are injected from cathode 215 to electron transport layer 214. Then, the electrons and the holes are supplied to light-emitting layer 213 and are thus recombined in light-emitting layer 213, as a result of which light-emitting layer 213 emits light.

Note that organic EL element 210 according to this embodiment has, as charge functional layers, hole injection layer 212 and electron transport layer 214, but the charge functional layers shall not be limited to such. Organic EL element 210 may include a different charge functional layer such as a hole transport layer, an electron injection layer, or an electron barrier layer.

Bank 220 is a barrier for partitioning each light-emitting layer 213 in organic EL element 210, and has opening 220a that surrounds light-emitting layer 213. Hole injection layer 212 and light-emitting layer 213 are formed inside opening 220a of bank 220. In this embodiment, hole injection layer 212 and light-emitting layer 213 ride on the lateral wall (lateral face) which constitutes the surface of bank 220.

At the lateral wall of bank 220, the ends of light-emitting layer 213 are located in the vicinity of but do not extend beyond the ends of hole injection layer 212. In other words, the tips of the ends of hole injection layer 212 are located as high as or higher than the tips of the ends of light-emitting layer 213.

Accordingly, in the location near the tips of the ends of both hole injection layer 212 and light-emitting layer 213 (region A enclosed by a dashed circle in FIG. 4), hole injection layer 212 and electron transport layer 214 are either close to or in contact with each other. In other words, light-emitting layer 213 which is located between hole injection layer 212 and electron transport layer 214 is formed, leaving the portions where the ends of hole injection layer 212 that rides on the lateral wall of bank 220 and electron transport layer 214 are close to or in contact with each other. In this embodiment, the ends of hole injection layer 212 are in contact with electron transport layer 214 in region A without having light-emitting layer 213 in between. In the portion at which hole injection layer 212 and electron transport layer 214 are close to or in contact with each other, the same resistance behavior as exhibited by one resistance element having electrical resistance properties can be observed.

Thus, resistance element 10 is formed as a resistance circuit connected in parallel to a main light-emitting portion of organic EL element 210 in the center of bank 220, in the state where a portion of hole injection layer 212 on the lateral wall of bank 220 and electron transport layer 214 are close to or in contact with each other. In other words, resistance element 10 is a portion at which hole injection layer 212 and electron transport layer 214 are close to or in direct contact with each other without having light-emitting layer 213 in between (i.e., a boundary between hole injection layer 212 and electron transport layer 214), and is formed using one or more components making up organic EL element 210. The portion at which hole injection layer 212 and electron transport layer 214 are close to or in contact with each other is not necessary as a matter of fact, but by intentionally forming such a portion, resistance element 10, which is connected in parallel to organic EL element 210, is formed in each bank 220.

Resistance element 10 having the configuration as described above is formed using one or more materials composing organic EL element 210, and therefore, the resistance of resistance element 10 becomes higher due to the deterioration caused by the energization of resistance element 10, and resistance gradually increases over time.

In this case, by using, as the material of hole injection layer 212, a material having lower resistance than the material of light-emitting layer 213, it is possible to easily increase, for resistance element 10 than for organic EL element 210, the rate at which resistance increases (resistance increase rate) due to deterioration after energization.

Bank 220 may be composed of an organic material such as resin or of an inorganic material. The organic material is, for example, acrylic resin, polyimide, or novorak phenol resin. The inorganic material is, for example, silicon oxide (SiO₂) or silicon nitride (Si₃N₄). Note that it is desirable that bank 220 be formed using a material having organic solvent tolerance and insulating properties. Moreover, since etching and bake processes may possibly be performed, it is also desirable that bank 220 be formed using a material having high tolerance against these processes.

Additionally, it is recommended that the surface of bank 220 be liquid-repellent. By applying liquid-repellent treatment such as fluorine-plasma treatment to bank 220, for example, it is possible to give bank 220 liquid repellency and render the surface of bank 220 to be liquid-repellent. Note that the surface of bank 220 may be rendered liquid-repellent by forming bank 220 using an organic material that has liquid repellency, instead of applying liquid-repellent treatment to bank 220. For example, a material including a fluorine resin such as a fluoridated polyolefin resin, a fluoridated polyimide resin, a fluoridated poly-acryl resin can be used as the organic material that has liquid repellency.

A sealing layer is formed to cover cathode 215 although not shown in the diagram. For example, an organic material such as a fluorine resin, an oxide material such as oxide silicon (SiO₂), oxide germanium (GeO), or oxide aluminum (Al₂O₃), or a nitride material such as oxynitride silicon (SiON) or nitride silicon (SiN) may be used as the material of the sealing layer. Note that, since organic EL display device 1 according to this embodiment is of top emission type, a light transmissive material is used as the material of the sealing layer.

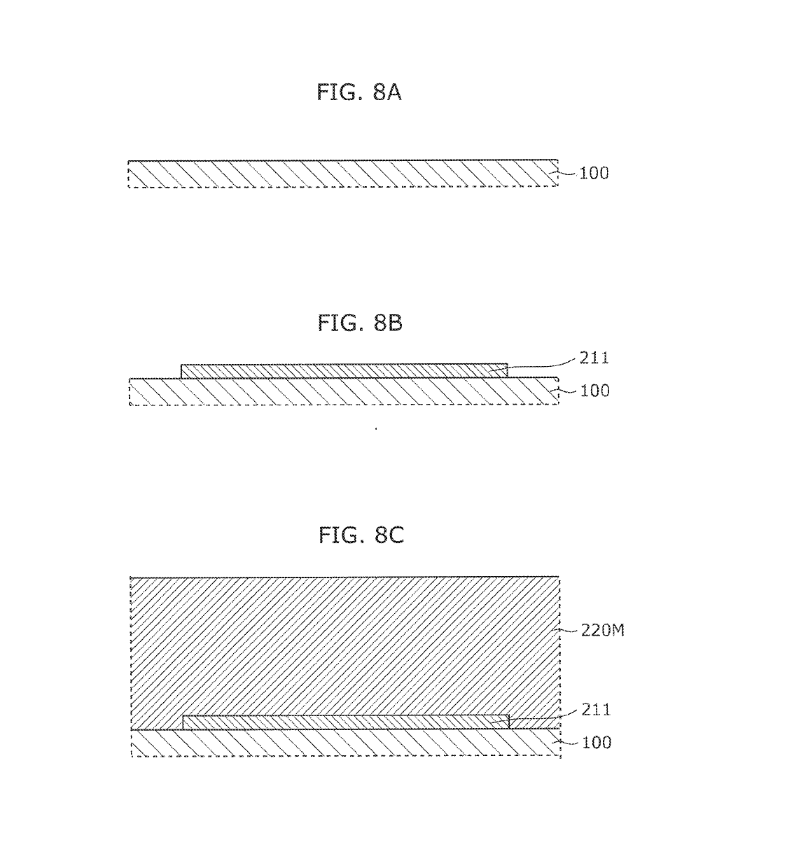

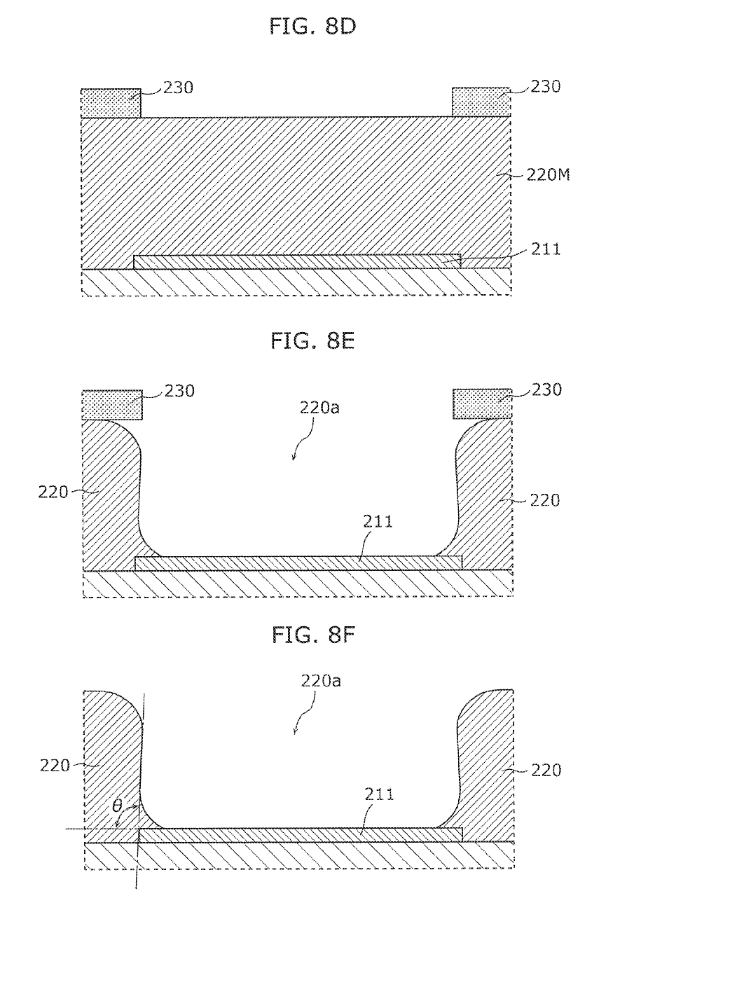

Next, advantageous effects of organic EL display device 1 according to this embodiment will be described with reference to FIG. 5 and FIG. 6 in comparison with a conventional organic EL display device. FIG. 5 is a diagram illustrating a change in the amount of current when organic EL element 210X in a conventional organic EL display device deteriorates. FIG. 6 is a diagram illustrating a change in the amount of current when organic EL element 210 and resistance element 10 in organic EL display device 1 according to the embodiment deteriorate.

With a conventional organic EL display device, after the energization of organic EL element 210X by means of pixel circuit 120 which is a constant current circuit, the current flows to organic EL element 210X and organic EL element 210X emits light, as illustrated in (a) in FIG. 5.

Here, a light-emitting layer or a charge functional layer of organic EL element 210X deteriorates over time after energization etc. Therefore, the resistance of organic EL element 210X gradually increases over time due to the deterioration caused by the energization of organic EL element 210X. In other words, the resistance of organic EL element 210X becomes higher over time after energization during normal operation.

As a result, the amount of current that flows from pixel circuit 120, which is a constant current circuit, to organic EL element 210X remains unchanged, but the luminance of organic EL element 210X gradually decreases because resistance in organic EL element 210X becomes higher over time. This causes screen burn-in in white display pixels displaying, for example, a menu screen.

In contrast, in organic EL display device 1 according to this embodiment, resistance element 10, having resistance that increases at a higher rate than that of organic EL element 210 due to energization, is connected in parallel to organic EL element 210.

With this, after the energization of organic EL element 210 by means of pixel circuit 120 which is a constant current circuit, the current which is supplied from pixel circuit 120 in accordance with the resistance ratio between organic EL element 210 and resistance element 10 is split, and a predetermined amount of current flows to organic EL element 210 and resistance element 10, respectively. Accordingly, organic EL element 210 emits light.

Here, the resistance of organic EL element 210 and the resistance of resistance element 10 become higher as the resistance values thereof gradually increase over time due to deterioration after energization during normal operation, but the resistance of resistance element 10 increases, due to energization, at a higher rate than the resistance of organic EL element 210. The resistance ratio between organic EL element 210 and resistance element 10 therefore automatically changes so that the resistance of resistance element 10 is higher than the resistance of organic EL element 210. As a result, it is possible to increase a relative amount of energization for organic EL element 210 with respect to the amount of energization for resistance element 10, as illustrated in (b) in FIG. 6. With this, it is possible to prevent luminance decrease caused by the deterioration of organic EL element 210. It is therefore possible to prevent screen burn-in due to the deterioration of organic EL elements 210.

In particular, in organic EL display device 1 according to this embodiment, resistance element 10 is formed using one or more components that make up organic EL element 210 instead that a circuit element such as a resistor is separately mounted on organic EL display device 1. More specifically, resistance element 10 is formed in the state where hole injection layer 212 and electron transport layer 214 are made close to or in contact with each other at the lateral wall of bank 220 in EL portion 200.

This can achieve a small organic EL display device compared to the case of separately mounting a circuit element such as a resistor to be connected in parallel to organic EL element 210 in each pixel 110.

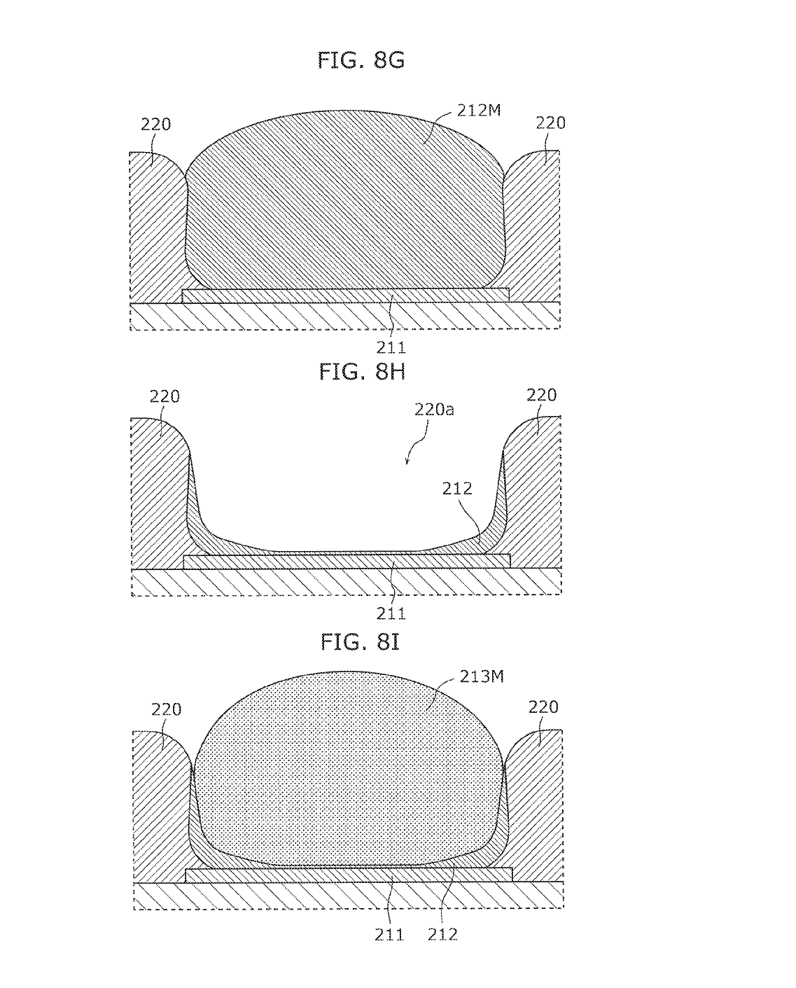

Moreover, the amount of current that relatively flows to resistance element 10 connected in parallel to organic EL element 210 can be controlled by the concentration of barium doped in electron transport layer 214 in organic EL element 210. This point will be described with reference to FIG. 7. FIG. 7 is a diagram illustrating a change in the luminance of organic EL element 210 with respect to a period of energization time. In addition, FIG. 7 illustrates a change in luminance when the concentration of barium doped in electron transport layer 214 of organic EL element 210 is 5%, 20%, and 40%. Note that FIG. 7 shows experimental values.

As illustrated in FIG. 7, the higher the concentration of barium doped in electron transport layer 214 of organic EL element 210 gets, the lower the luminance of organic EL element 210 becomes in a short period of energization time. In other words, organic EL element 210 can easily deteriorate as the concentration of barium doped in electron transport layer 214 of organic EL element 210 gets higher. That is to say that resistance easily becomes higher. This is because resistance change rate of electron transport layer 214 changes because of deterioration after energization, depending on the concentration of barium doped in electron transport layer 214. Thus, it is possible to control the amount of current that relatively flows to resistance element 10, by changing the concentration of barium doped in electron transport layer 214.

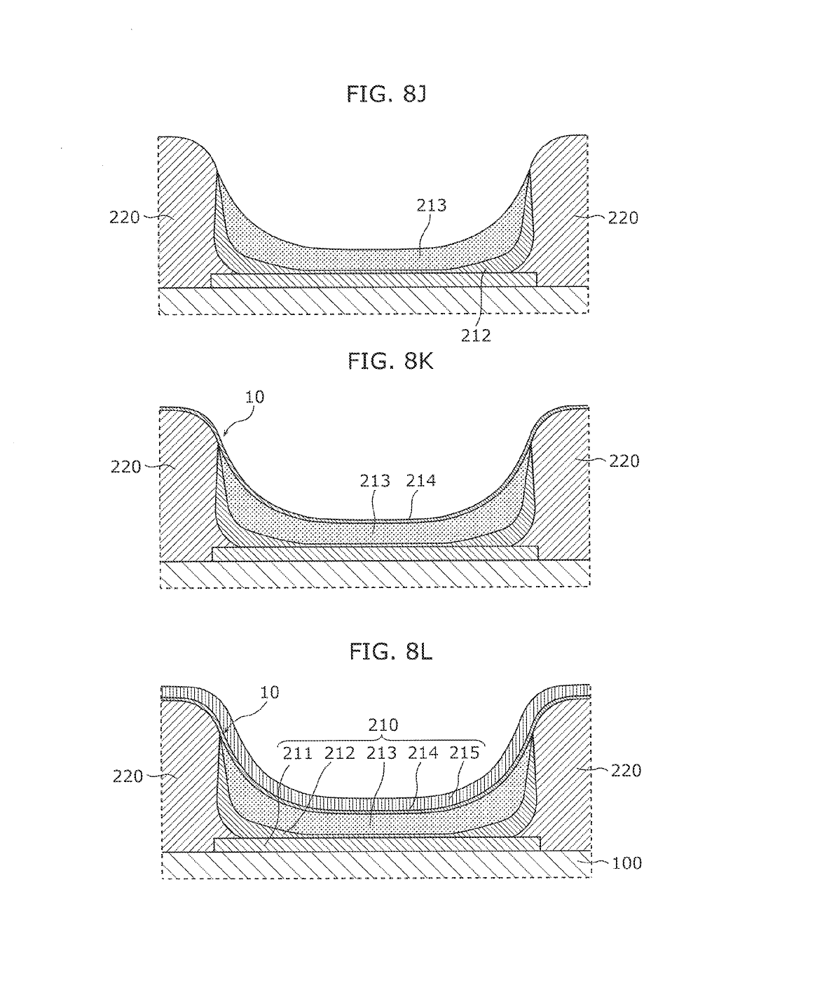

Next, a method for manufacturing organic EL display device 1 according to this embodiment will be described with reference to FIG. 8A through FIG. 8L. FIG. 8A through FIG. 8L are each a cross-sectional view of a process in the method for manufacturing organic EL display device 1 according to this embodiment.

First, TFT substrate 100 is prepared, as illustrated in FIG. 8A. TFT substrate 100 can be created, for example, by forming, on a substrate such as a glass substrate, circuit elements such as TFTs included in pixel circuit 120 and wirings, and covering the substrate with a planarization layer. Note that a contact hole is formed in a portion of the planarization layer. Through this contact hole, source electrode S2 of driving transistor DrTr in pixel circuit 120 of TFT substrate 100 is electrically connected to anode 211 of organic EL element 210.

Next, anode 211 of organic EL element 210 is formed on TFT substrate 100, as illustrated in FIG. 8B. For example, an aluminum alloy film is formed on TFT substrate 100 by means of sputtering and anode 211 that is composed of aluminum alloy and has a predetermined shape can be formed through photolithograpy and etching

Next, bank 220 having opening 220a is formed, as illustrated in FIG. 8C through FIG. 8F. More specifically, bank 220 is formed to surround the region where anode 211 has been formed.

In this case, the entire surface of TFT substrate 100 is coated, for example, by applying resist film 220M (e.g., a photosensitive resin) including a photoresist material, as the material of bank 220 to cover anode 211, as illustrated in FIG. 8C. Then, mask 230 having an opening is formed on resist film 220M, resist film 220M is subsequently exposed to light via mask 230, and then, a predetermined portion of resist film 220M is removed in a developing process using a developer so that anode 211 is exposed. Subsequently, heat treatment (e.g., bake process) of heating with the temperature ranging from 150 to 250 degrees Celsius is applied. With this heat treatment, the solvent remaining in resist film 220M vaporizes. Thus, it is possible to form bank 220 having opening 220a that allows anode 211 to be exposed, as illustrated in FIG. 8E. After that, mask 230 is removed as illustrated in FIG. 8F. Note that liquid-repellent treatment may be applied on the surface of bank 220 where necessary.

Moreover, when a portion of resist film 220M is removed using a developer so that opening 220a is formed, it is recommended that the portion of resist film 220M be removed so that angle θ (taper angle) between the bottom plane of opening 220a (surface of anode 211) and the lateral wall of bank 220 is greater than 90 degrees. In other words, it is recommended to make the lateral wall of bank 220 tilted so that the root of the lateral wall of bank 220 recedes more than the upper part of the lateral wall, by relatively increasing the amount of the portion to be removed from the root of bank 220. Taper angle θ (tilt angle) of the lateral wall of bank 220 can be controlled, for example, by adjusting the conditions under which resist film 220M is exposed to light.

Next, hole injection layer 212 is formed inside opening 220a of bank 220. In this embodiment, hole injection layer 212 is formed on anode 211 by applying, inside opening 220a of bank 220, first organic solvent 212M that includes an organic material composing hole injection layer 212, and then drying first organic solvent 212M, as illustrated in FIG. 8G and FIG. 8H.

In this case, first organic solvent 212M, in which the organic material composing hole injection layer 212 is dispersed, is firstly applied, as ink for printing and using inkjet printing method, inside opening 220a of bank 220, where anode 211 is exposed, as illustrated in FIG. 8G. Here, the surface of first organic solvent 212M bulges from opening 220a of bank 220 and forms a spherical shape due to surface tension.

Note that the method of applying first organic solvent 212M shall not be limited to inkjet printing method, and may be dispenser printing, nozzle coating, spin coating, letterpress printing, or intaglio printing method.

After that, first organic solvent 212M is dried. It is possible to dry first organic solvent 212M, for example, by applying heat treatment. With this, a solvent composition in first organic solvent 212M vaporizes, and it is thus possible to form thin-filmed hole injection layer 212 along the inner surface of opening 220a of bank 220, as illustrated in FIG. 8H. More specifically, it is possible to form hole injection layer 212 that rides on bank 220, extending from the bottom of opening 220a of bank 220 and along the lateral wall of bank 220. Note that by controlling temperature or time when heat treatment is applied, or by controlling pressure inside a chamber in the case of applying heat treatment in the chamber, it is possible to transform bulging first organic solvent 212M into hole injection layer 212 having desired thickness and shape.

Next, light-emitting layer 213 is formed inside opening 220a of bank 220. In this embodiment, light-emitting layer 213 is formed on hole injection layer 212 by applying, inside opening 220a of bank 220, second organic solvent 213M that includes an organic material (light-emitting material) composing light-emitting layer 213, and then drying second organic solvent 213M, as illustrated in FIG. 8I and FIG. 8J.

In this case, second organic solvent 213M, in which an organic material composing light-emitting layer 213 is dispersed, is applied, as ink for printing and using an inkjet printing method, inside opening 220a of bank 220, where hole injection layer 212 has been formed. Here, the surface of second organic solvent 213M bulges from opening 220a of bank 220 and forms a spherical shape due to surface tension.

Here, since the liquid repellency of second organic solvent 213M for forming light-emitting layer 213 is higher than that of first organic solvent 212M for forming hole injection layer 212, curvature is greater in the surface of second organic solvent 213M than in the surface of first organic solvent 212M.

Moreover, although second organic solvent 213M for forming light-emitting layer 213 (red-light emitting layer) of organic EL element for red color, second organic solvent 213M for forming light-emitting layer 213 (green-light emitting layer) of organic EL element for green color, and second organic solvent 213M for forming light-emitting layer 213 (blue-light emitting layer) of organic EL element for blue color are applied separately, it is also possible to apply these second organic solvents 213M at the same time by using an ink-jet apparatus having plural heads,

Note that the method of applying second organic solvent 213M shall not be limited to ink-jet printing method and may be dispenser printing, nozzle coating, spin coating, letterpress printing, or intaglio printing method.

After that, second organic solvent 213M is dried. It is possible to dry second organic solvent 213M, for example, by applying heat treatment. With this, a solvent composition in second organic solvent 213M vaporizes and it is thus possible to form a thin-filmed light-emitting layer 213, as illustrated in FIG. 8J. More specifically, it is possible to form light-emitting layer 213 that rides on bank 220, extending from the bottom of opening 220a of bank 220 and along the lateral wall of bank 220, as is formed hole injection layer 212. Note that by controlling temperature or time when heat treatment is applied, or by controlling pressure inside a chamber in the case of applying heat treatment in the chamber, it is possible to transform bulging second organic solvent 213M into light-emitting layer 213 having desired thickness and shape.

Here, in this embodiment, light-emitting layer 213 is formed so that the ends of light-emitting layer 213 do not extend beyond the ends of hole injection layer 212. More specifically, the tips of the ends of hole injection layer 212 either coincide with or are exposed from the tips of the ends of light-emitting layer 213. It is possible to easily form such a structure by causing taper angle θ at the lateral wall of bank 220 illustrated in FIG. 8F to be greater than 90 degrees. Moreover, as has already been mentioned above, by increasing the liquid repellency of second organic solvent 213M for forming light-emitting layer 213 more than that of first organic solvent 212M for forming hole injection layer 212, it is possible to easily cause the tips of the ends of hole injection layer 212 to either coincide with or be exposed from the tips of the ends of light-emitting layer 213.

Next, electron transport layer 214 is formed on light-emitting layer 213 to cover opening 220a of bank 220, as illustrated in FIG. 8K. An organic material made by adding barium to a low-molecular material can be used as the material of electron transport layer 214. Electron transport layer 214 is formed on the entire surface covering light-emitting layer 213 and bank 220, for example, using an evaporation method.

Here, since the tips of the ends of hole injection layer 212 either coincide with or are exposed from the tips of the ends of light-emitting layer 213, hole injection layer 212 and electron transport layer 214 are close to or in contact with each other at the lateral wall of bank 220. Thus, resistance element 10 is formed near a boundary between hole injection layer 212 and electron transport layer 214.

Next, cathode 215 is formed on electron transport layer 214, as illustrated in FIG. 8L. It is possible to form cathode 215 composed of ITO film, for example, by forming ITO on electron transport layer 214 by means of sputtering.

In this way, it is possible to form organic EL element 210 having anode 211, hole injection layer 212, light-emitting layer 213, electron transport layer 214, and cathode 215. Note that a sealing layer may be subsequently formed to cover the entire surface of cathode 215. With this, it is possible to form EL portion 200 on TFT substrate 100.

Note that organic EL display device 1 can be achieved by attaching, to EL portion 200 with an attaching layer, color-filter substrate 300 that has separately been created.

As has been described above, organic EL display device 1 according to this embodiment has, in each of pixels 110, organic EL element 210 and resistance element 10 that is connected in parallel to organic EL element 210. In addition, organic EL element 210 and resistance element 10 have properties such that resistance gradually increases over time after the energization of these elements. Moreover, the resistance of resistance element 10 changes at a rate higher than the resistance of organic EL element 210.

With the configuration as described above, it is possible to automatically increase the amount of energization provided for organic EL element 210 as the deterioration of organic EL element 210 progresses due to the energization of organic EL element 210 during normal operation. Thus, it is possible to prevent luminance decrease caused by the deterioration of organic EL element 210. As a result, it is possible to prevent screen burn-in caused by the deterioration of organic EL elements 210.

### Variations Etc.

Although a display device and a method for manufacturing the display device have been described based on the embodiment so far, the technology disclosed in the present disclosure shall not be limited to the aforementioned embodiment.

In the aforementioned embodiment, resistance element 10 is formed from one or more components making up organic EL element 210, but shall not be limited to such. Resistance element 10 needs to be a variable resistance which increases over time. In this case, resistance element 10 shall not be limited to one whose resistance increases due to the deterioration of the material of organic EL element 210.

Forms obtained by various modifications to the foregoing embodiment that can be conceived by a person skilled in the art as well as forms realized by arbitrarily combining components and functions in the embodiment within the scope of the essence of the present disclosure are included in the present disclosure.

Although only an exemplary embodiment of the present disclosure has been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure can be widely utilized for various electronic appliances such as a TV set, a personal computer, or a cell phone equipped with a display device (display panel) such as an organic EL display device.

1. A display device comprising:
a light-emitting element that is provided in each of pixels and emits light according to flow of current; and
a resistance element that is provided in each of the pixels and is connected in parallel to the light-emitting element, wherein
resistance of the light-emitting element and resistance of the resistance element increase over time after energization of the light-emitting element and the resistance element, and
the resistance of the resistance element changes at a higher rate than the resistance of the light-emitting element.

2. The display device according to claim 1, wherein
the light-emitting element includes a first charge functional layer, a light-emitting layer disposed on the first charge functional layer, and a second charge functional layer disposed on the light-emitting layer, and
the resistance element is formed in a state where the first charge functional layer and the second charge functional layer are close to or in contact with each other.

3. The display device according to claim 2, further comprising:
a bank that has an opening, wherein
the first charge functional layer and the light-emitting layer ride on the bank, extending from a bottom of the opening and along a lateral wall of the bank,
the second charge functional layer covers the opening, and
the resistance element is formed in a state where a portion of the first charge functional layer on the lateral wall of the bank and the second charge functional layer are close to or in contact with each other.

4. The display device according to claim 3, wherein
an angle between a bottom plane of the opening and the lateral wall of the bank is greater than 90 degrees.

5. The display device according to claim 2, wherein
resistance of the first charge functional layer is lower than the resistance of the light-emitting layer.

6. The display device according to claim 2, wherein
the light-emitting layer has higher liquid repellency than liquid repellency of the first charge functional layer.

7. The display device according to claim 2, wherein
the second charge functional layer includes barium.

8. The display device according to claim 2, wherein
the first charge functional layer is a hole injection layer, and
the second charge functional layer is an electron transport layer.

9. The display device according to claim 1, further comprising:
a constant current circuit that supplies current to the light-emitting element in each of the pixels.

10. The display device according to claim 9, wherein
the constant current circuit has a driving transistor that controls current that flows to the light-emitting element, and a switching transistor that is connected to a control terminal of the driving transistor and controls conduction and non-conduction of the driving transistor.

11. The display device according to claim 1, wherein
the light-emitting element is an organic electroluminescent (EL) element.

12. A method of manufacturing a display device, the method comprising:
forming a bank that has an opening;
forming a first charge functional layer by applying a first material inside the opening and drying the first material applied;
forming a light-emitting layer on the first charge functional layer by applying a second material inside the opening and drying the second material applied; and
forming a second charge functional layer on the light-emitting layer to cover the opening, wherein
the first charge functional layer and the second charge functional layer are close to or in contact with each other at a lateral wall of the bank.
